(19) United States
(12) Patent Application Publication
(10) Pub. No.: US 2007/0210321 A1
(43) Pub. Date: Sep. 13, 2007

(54) Edge light-emitting device and manufacturing method thereof

(75) Inventor: Tasuku Satou, Kanagawa (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/713,679

(22) Filed: Mar. 5, 2007

(30) Foreign Application Priority Data
Mar. 8, 2006 (JP) 2006-062812

(51) Int. Cl. H01L 33/00

(52) U.S. Cl. 257/79

(57) ABSTRACT

An edge light-emitting device having, on a light permeable substrate, a stacked structure including a pair of electrodes and at least one light emitting layer interposed between the electrodes, in which light emission is taken-out from a light emitting edge of the stacked structure, wherein at least one non-light emitting edge other than the light emitting edge for taking out the light emission, an angle formed by the non-light emitting edge relative to a surface of the substrate supporting the stacked structure or a surface opposed to the surface of the substrate supporting the stacked structure is an acute angle, and the non-light emitting edge has a light reflection layer. An edge light-emitting device excellent in production feasibility and a manufacturing method thereof are provided.

### CROSS-REFERENCE TO RELATED APPLICATION

This application claims priority under 35 USC 119 from Japanese Patent Application No. 2006-62812, the disclosure of which is incorporated by reference herein.

### BACKGROUND OF THE INVENTION

1. Field of the Invention

The present invention concerns an edge light-emitting device and a manufacturing method thereof. More particularly, it relates to an edge light-emitting device excellent in producing feasibility and a manufacturing method thereof.

2. Description of the Related Art

In recent years, various functional devices have been developed and proposed. For example, devices that emit light by application of a voltage, such as an organic electroluminescence device (hereinafter sometimes referred to as an organic EL device) and an inorganic electroluminescence device (hereinafter sometimes referred to as an inorganic EL device), and a photoelectronic conversion device that generates power by irradiation of light are known.

The organic electroluminescence devices, which use a thin film material that undergoes excitation by application of a current to emit light, obtain high-brightness light emission at low voltage, and therefore, have broad potential applications in fields such as cellular phone displays, personal digital assistants (PDA), computer displays, car information displays, TV monitors, and general illumination, and also have advantages of reducing the thickness, weight, size, and power consumption of the devices in the respective fields. Accordingly, such a device has the potential to become the leading device in the future electronic display market. However, there are still many technical problems to overcome, such as with respect to luminescence brightness and color tone, durability under various ambient operating conditions, and mass productivity at low cost, in order for these devices to be practically used in these fields in place of conventional display devices.

One problem of light emitting devices is that the efficiency for taking out light emission is low. Light generated in a light emission layer passes through a transparent substrate or a transparent electrode at a take-out surface and is taken-out to the outside. However, since the difference in refractive index is large between the substrate or the electrode and the light emission layer or other functional layers, and the difference in refractive index is large between the substrate or the electrode and the external air, the emitted light repeats total reflection in the device and is absorbed in the inside, so that the ratio of light taken-out effectively to the outside is generally 30% or less of the amount of emitted light.

As means for improving the efficiency of taking out the light, an edge light-emitting device is known. Since the edge light-emitting device can effectively take-out a waveguide light that can not be taken out from the planar surface of the substrate to the outside, it has an advantage of increasing the light emission efficiency more easily than the surface light emitting device. However, in the case of taking out the light confined within the substrate from the edge of the substrate, in order to realize high take-out efficiency, it is necessary to adopt a structure capable of effectively preventing the light leakage from edges other than the light take-out edge and emitting light only from the light emitting edge. As a method of preventing light leakage at an edge not intended for taking-out light, JP-A No. 10-208874, for example, discloses that an organic EL device is formed on a light guide member, an edge not taking-out light is formed vertically to the surface of the substrate supporting the stacked structure or to the substrate surface opposite thereto, and Al is vapor deposited as a light reflection agent at the vertical edge. However, since the vertical edge of the thin layer substrate has an extremely small area and it is not technically easy to provide the aluminum reflection layer by vapor deposition at the vertical edge, even if thist could be attained, it would not be efficient in view of industrial productivity due to, for example, an increase in the number of processes or an increase in the size of the device, and thus, the method is lacking in actual realizability.

JP-A No. 2001-244067 proposes adhering a plastic sheet kneaded with a light reflection material such as titanium oxide or zinc oxide as a light reflection material to the edge not taking out the light. However, since the edge of the thin layer substrate has an extremely small area, it is not easy to adhere the plastic sheet at a necessary adhesion strength, and this is also lacking in actual realizability.

JP-A No. 2003-168553 proposes a method of forming a saw-teeth-like concave-convex shape on the surface of a transparent substrate opposite the surface for supporting the light emitting device and covering the concave-convex shape portion with a light reflection layer to thereby decrease the total reflection and improve the light take-out efficiency.

However, light leakage to portions other than the light take-out edge cannot be prevented effectively even by such means, and means for further improvement are desired.

### SUMMARY OF THE INVENTION

The present invention has been made in view of the above circumstances and provides an edge light-emitting device having, on a light permeable substrate, a stacked structure comprising a pair of electrodes and at least one light emitting layer interposed between the electrodes, in which light emission is taken-out from a light emitting edge of the stacked structure, wherein at least one non-light emitting edge other than the light emitting edge for taking out the light emission, an angle formed by the non-light emitting edge relative to a surface of the substrate supporting the stacked structure or a surface opposed to the surface of the substrate supporting the stacked structure is an acute angle, and the non-light emitting edge has a light reflection layer.

A second aspect of the present invention is to provide a method of manufacturing an edge light-emitting device at least including:

(1) disposing a stacked structure comprising a pair of electrodes and at least one light emitting layer interposed between the electrodes, on a light permeable substrate;

(2) subsequently tapering an edge that does not take out light emission; and

(3) disposing a light reflection layer at the tapered edge.

A third aspect of the present invention is to provide a method of manufacturing an edge light-emitting device at least including:

(1) tapering an edge, of a light permeable substrate, that does not constitute a light emission taking-out edge;

(2) subsequently disposing a stacked structure comprising a pair of electrodes and at least one light emitting layer interposed between the electrodes, on the substrate; and

(3) disposing a light reflection layer at the tapered edge.

### BRIEF DESCRIPTION OF THE DRAWINGS

FIG. 1 is a conceptual view showing an edge shape, in which an edge of a substrate has been tapered into a planar shape.

FIG. 2 is a conceptual view showing an edge shape, in which an edge of a substrate has been tapered to have a stepwise shape.

FIG. 3 is a conceptual view showing an edge shape, in which an edge of a substrate has been tapered to have a convex shape.

FIG. 4 is a conceptual view showing an edge shape, in which an edge of a substrate has been tapered to have a concave shape.

FIG. 5 is a conceptual view showing an edge shape, in which an edge of a substrate has been tapered to have a corrugated shape.

FIG. 6 is a conceptual view showing an edge shape, in which an edge has been tapered to have a planar shape and stepwise shape.

FIG. 7 is a conceptual view showing an edge shape, in which an edge has been tapered to have a stepwise shape and a reversely tapered planar shape.

FIG. 8 is a conceptual view of a cross sectional shape of a light taking-out edge of a light emitting device which has been subjected to tapering.

### DETAILED DESCRIPTION OF THE INVENTION

The present invention provides an edge light-emitting device that is excellent in production feasibility and a manufacturing method thereof and, particularly, provides an edge light-emitting device having improved light take-out efficiency and excellent production feasibility, as well as a manufacturing process thereof.

The light emitting device of the invention is an edge light-emitting device having, on a light permeable substrate, a stacked structure comprising a pair of electrodes and at least one light emitting layer interposed between the electrodes, in which light emission is taken-out from a light emitting edge of the stacked structure, wherein at least one non-light emitting edge other than the light emitting edge for taking out the light emission, an angle formed by the non-light emitting edge relative to a surface of the substrate supporting the stacked structure or a surface opposed to the surface of the substrate supporting the stacked structure is an acute angle, and the non-light emitting edge has a light reflection layer. Preferably, the angle formed by the non-light emitting edge at three surfaces of the edge other than the edge for taking out the light emission is an acute angle and the non-light emitting edge has a light reflection layer.

The non-light emitting edge other than the edge for taking-out the light emission of the edge light-emitting device having the constitution of the invention has an acute angle formed by the non-light emitting edge relative to the surface of the substrate supporting the stacked structure or the surface of the substrate opposite thereto. Accordingly, the area of the non-light emitting edge is larger than the cross sectional area and can firmly carry the light reflection layer. Another prominent feature is that the light reflection layer can be disposed by vapor deposition or coating method in the direction vertical to the substrate, so that it can be practiced by the same step as a step of providing the functional layer of the light emitting device, particularly, without changing the position or the direction of the substrate. Accordingly, this is extremely excellent in the production feasibility

Preferably, the angle formed at the non-light emitting edge is 30° or more and 60° or less.

Preferably, the area at the non-light emitting edge is larger by 15% or more than the cross sectional area of the non-light emitting edge.

Preferably, the light reflection layer is a film formed by vapor deposition. Preferably, the vapor deposition film is made of a metal or a metal oxide.

Preferably, the light emitting device is an organic electroluminescence device or an inorganic electroluminescence device.

The edge light-emitting device of the invention is manufactured by a manufacturing method including a step of disposing a stacked structure comprising a pair of electrodes and at least one layer of light emitting layers interposed between the electrodes on a light permeable substrate, a step of subsequently tapering the edge that does not take out light emission, and a step of disposing a light reflection layer at the tapered edge.

Another manufacturing method of the edge light-emitting device of the invention is a manufacturing method including a step of tapering edge, of a light permeable substrate, that does not constitute a light emission taking-out edge, a step of subsequently disposing a stacked structure comprising a pair of electrodes and at least one light emitting layer interposed between the electrodes, on the substrate, and a step of disposing a light reflection layer to the tapered edge.

The present invention provides an edge light-emitting device excellent in the production feasibility and a manufacturing method thereof and, particularly provides an edge light-emitting device having improved light take-out efficiency and excellent production feasibility, as well as a manufacturing process thereof

1. Organic Electroluminescence Device

An organic electroluminescence device in the present invention may have, in addition to the light-emitting layer, conventionally known organic compound layers such as a positive hole-transport layer, an electron-transport layer, a blocking layer, an electron-injection layer and a positive hole-injection layer.

In the following, the organic electroluminescence device of the present invention will be described in detail.

1) Layer Configuration

<Electrode>

At least one of a pair of electrodes of the organic electroluminescence device of the present invention is a transparent electrode, and the other one is a rear surface electrode. The rear surface electrode may be transparent or non-transparent.

<Configuration of Organic Compound Layer>

A layer configuration of the at least one organic compound layer can be appropriately selected, without particular restriction, depending on an application of the organic electroluminescence device and an object thereof. However, the organic compound layers are preferably formed on the transparent electrode or the rear surface electrode. In these cases, the organic compound layers are formed on front surfaces or one surface on the transparent electrode or the rear surface electrode.

A shape, magnitude and thickness of the organic compound layers can be appropriately selected, without particular restriction, depending on applications thereof.

Examples of specific layer configurations include those cited below, but the present invention is not restricted to those configurations.
Anode/positive hole-transport layer/light-emitting layer/electron-transport layer/cathode,
Anode/positive hole-transport layer/light-emitting layer/blocking layer/electron-transport layer/cathode,
Anode/positive hole-transport layer/light-emitting layer/blocking layer/electron-transport layer/electron-injection layer/cathode,
Anode/positive hole-injection layer/positive hole-transport layer/light-emitting layer/blocking layer/electron-transport layer/cathode, and
Anode/positive hole-injection layer/positive hole-transport layer/light-emitting layer/blocking layer/electron-transport layer/electron-injection layer/cathode.

In the following, the respective layers will be described in detail.

2) Positive Hole-Transport Layer

The positive hole-transport layer that is used in the present invention includes a positive hole transporting material. For the positive hole transporting material, any material can be used without particular restriction as far as it has either one of a function of transporting holes or a function of blocking to electrons injected from the cathode. As the positive hole transporting material that can be used in the present invention, either one of a low molecular weight hole transporting material and a polymer hole transporting material can be used.

Specific examples of the positive hole transporting material that can be used in the present invention include a carbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, a polysilane-based compound, a poly(N-vinylcarbazole) derivative, an aniline-based copolymer, electric conductive polymers or oligomers such as a thiophene oligomer and polythiophene, and polymer compounds such as a polythiophene derivative, a polyphenylene derivative, a polyphenylenevinylene derivative and a polyfluorene derivative.

These compounds may be used singularly or in a combination of two or more.

A thickness of the positive hole-transport layer is preferably 10 nm to 400 nm and more preferably 50 nm to 200 nm.

3) Hole-Injection Layer

In the present invention, a positive hole-injection layer may be disposed between the positive hole-transport layer and the anode.

The positive hole-injection layer is a layer that makes it easy for holes to be injected easily from the anode to the positive hole-transport layer, and specifically, a material having a small ionization potential among the positive hole transporting materials cited above is preferably used. For instance, a phthalocyanine compound, a porphyrin compound and a star-burst type triarylamine compound can be preferably used.

A film thickness of the positive hole-injection layer is preferably 1 nm to 300 nm.

4) Light-Emitting Layer

A light-emitting layer in the present invention comprises at least one light emitting material, and may comprise as necessary other compounds such as a positive hole transporting material, an electron transporting material, and a host material.

Any of light emitting materials can be used without particular restriction. Either of fluorescent emission materials or phosphorescent emission materials can be used, but the phosphorescent emission materials are preferred in view of the luminescent efficiency.

Examples of the above-described fluorescent emission materials include, for example, a benzoxazole derivative, a benzimidazole derivative, a benzothiazole derivative, a styrylbenzene derivative, a polyphenyl derivative, a diphenylbutadiene derivative, a tetraphenylbutadiene derivative, a naphthalimide derivative, a coumarin derivative, a perylene derivative, a perinone derivative, an oxadiazole derivative, an aldazine derivative, a pyralidine derivative, a cyclopentadiene derivative, a bis-styrylanthracene derivative, a quinacridone derivative, a pyrrolopyridine derivative, a thiadiazolopyridine derivative, a styrylamine derivative, aromatic dimethylidene compounds, a variety of metal complexes represented by metal complexes or rare-earth complexes of 8-quinolynol, polymer compounds such as polythiophene, polyphenylene and polyphenylenevinylene, organic silanes, and the like. These compounds may be used singularly or in a combination of two or more.

The phosphorescent emission material is not particularly limited, but an ortho-metal complex or a porphyrin metal complex is preferred.

The ortho-metal complex referred to herein is a generic designation of a group of compounds described in, for instance, Akio Yamamoto, Yuki Kinzoku Kagaku, Kiso to Oyo (“Organic Metal Chemistry, Fundamentals and Applications”) (Shokabo, 1982), pp. 150 and 232, and H. Yersin, Photochemistry and Photophysics of Coordination Compounds (New York: Springer-Verlag, 1987), pp. 71-77 and pp. 135-146. The ortho-metal complex can be advantageously used as a light emitting material because high brightness and excellent emitting efficiency can be obtained.

As a ligand that forms the ortho-metal complex, various kinds can be cited and are described in the above-mentioned literature as well. Examples of preferable ligands include a 2-phenylpyridine derivative, a 7,8-benzoquinoline derivative, a 2-(2-thienyl)pyridine derivative, a 2-(1-naphtyl)pyridine derivative and a 2-phenylquinoline derivative. The derivatives may be substituted by a substituent as needs arise. Furthermore, the ortho-metal complex may have other ligands than the ligands mentioned above.

An ortho-metal complex used in the present invention can be synthesized according to various kinds of known processes such as those described in Inorg. Chem., 1991, Vol. 30, pp. 1685; Inorg. Chem., 1988, Vol. 27, pp. 3464; Inorg. Chem., 1994, Vol. 33, pp. 545; Inorg. Chim. Acta, 1991, Vol. 181, pp. 245; J. Organomet. Chem., 1987, Vol. 335, pp. 293 and J. Am. Chem. Soc., 1985, Vol. 107, pp. 1431.

Among the ortho-metal complexes, compounds emitting from a triplet exciton can be preferably employed in the present invention from the viewpoint of improving emission efficiency.

Furthermore, among the porphyrin metal complexes, a porphyrin platinum complex is preferable.

The phosphorescent light emitting materials may be used singularly or in a combination of two or more. Furthermore, a fluorescent emission material and a phosphorescent emission material may be simultaneously used.

A host material is a material that has a function of causing an energy transfer from an excited state thereof to the fluorescent emission material or the phosphorescent emission material to cause light emission from the fluorescent emission material or the phosphorescent emission material.

As the host material, as long as a compound can transfer exciton energy to a light emitting material, any compound can be appropriately selected and used depending on an application without particular restriction. Specific examples thereof include: a carbazole derivative; a triazole derivative; an oxazole derivative; an oxadiazole derivative; an imidazole derivative; a polyarylalkane derivative; a pyrazoline derivative; a pyrazolone derivative; a phenylenediamine derivative; an arylamine derivative; an amino-substituted chalcone derivative; a styrylanthracene derivative; a fluorenone derivative; a hydrazone derivative; a stilbene derivative; a silazane derivative; an aromatic tertiary amine compound; a styrylamine compound; an aromatic dimethylidene-based compound; a porphyrin-based compound; an anthraquinonedimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; various kinds of metal complexes typified by metal complexes of a 8-quinolinol derivative, metal phthalocyanine, and metal complexes with benzoxazole or benzothiazole as a ligand; polysilane compounds; a poly(N-vinylcarbazole) derivative; an aniline-based copolymer; electric conductive polymers or oligomers such as a thiophene oligomer and polythiophene; polymer compounds such as a polythiophene derivative, a polyphenylene derivative, a polyphenylenevinylene derivative and a polyfluorene derivative; and like. These compounds can be used singularly or in a combination of two or more.

A content of the host material in the light-emitting layer is preferably in the range of 0 to 99.9 mass percent and more preferably in the range of 0 to 99.0 mass percent.

5) Blocking Layer

In the present invention, a blocking layer may be disposed between the light-emitting layer and the electron-transport layer. The blocking layer is a layer that inhibits excitons generated in the light-emitting layer from diffusing and holes from penetrating to a cathode side.

A material that is used in the blocking layer may be a general electron transporting material, as long as it can receive electrons from the electron-transport layer and deliver them to the light-emitting layer, without being particularly restricted. Examples thereof include a triazole derivative; an oxazole derivative; an oxadiazole derivative; a fluorenone derivative; an anthraquinodimethane derivative; an anthrone derivative; a diphenylquinone derivative; a thiopyran dioxide derivative; a carbodiimide derivative; a fluorenylidenemethane derivative; a distyrylpyrazine derivative; heterocyclic tetracarboxylic anhydrides such as naphthalene perylene; a phthalocyanine derivative; various kinds of metal complexes typical in metal complexes of a 8-quinolinol derivative, metal phthalocyanine, and metal complexes with benzoxazole or benzothiazole as a ligand; electric conductive polymer oligomers such as an aniline-based copolymer, a thiophene oligomer and polythiophene; and polymer compounds such as a polythiophene derivative, a polyphenylene derivative, a polyphenylenevinylene derivative and a polyfluorene derivative. These can be used singularly or in a combination of two or more.

6) Electron-Transport Layer

In the present invention, an electron-transport layer including an electron transporting material can be disposed.

The electron transporting material can be used without particular restriction, as long as it has either one of a function of transporting electrons or a function of blocking holes injected from the an anode. The electron transporting materials that were cited in the explanation of the blocking layer can be preferably used.

A thickness of the electron-transport layer is preferably 10 nm to 200 nm and more preferably 20 nm to 80 nm.

When the thickness exceeds 1000 nm, the driving voltage increases in some cases. When it is less than 10 nm, the light-emitting efficiency of the light-emitting element may be greatly deteriorated, which is not preferable.

7) Electron-Injection Layer

In the present invention, an electron-injection layer can be disposed between the electron-transport layer and the cathode.

The electron-injection layer is a layer by which electrons can be readily injected from the cathode to the electron-transport layer. Specifically, lithium salts such as lithium fluoride, lithium chloride and lithium bromide; alkali metal salts such as sodium fluoride, sodium chloride and cesium fluoride; and electric insulating metal oxides such as lithium oxide, aluminum oxide, indium oxide and magnesium oxide can be preferably used.

A film thickness of the electron-injection layer is preferably 0.1 nm to 5 nm.

8) Producing Method of Element

The organic compound layers in the present invention can be preferably formed by any method of dry layering methods such as a vapor deposition method and a sputtering method, and wet layering methods such as a dipping method, a spin coating method, a dip coating method, a casting method, a die coating method, a roll coating method, a bar coating method and a gravure coating method.

Among these, from the viewpoints of emission efficiency and durability, the dry methods are preferable.

In the following, a substrate and electrodes used in the organic electroluminescence device of the present invention will be described in detail.

9) Substrate

The substrate to be applied in the present invention is preferably impermeable to moisture or very slightly permeable to moisture. Furthermore, the substrate preferably does not scatter or attenuate light emitted from the organic compound layer. Specific examples of materials for the substrate include YSZ (zirconia-stabilized yttrium); inorganic materials such as glass; polyesters such as polyethylene terephthalate, polybutylene phthalate and polyethylene naphthalate; and organic materials such as polystyrene, polycarbonate, polyethersulfon, polyarylate, aryldiglycolcarbonate, polyimide, polycycloolefin, norbornene resin, poly(chlorotrifluoroethylene), and the like.

In case of employing an organic material, it is preferred to use a material excellent in heat resistance, dimensional stability, solvent-resistance, electrical insulation, workability, low air-permeability, and low moisture-absorption. These can be used singularly or in a combination of two or more.

There is no particular limitation as to the shape, the structure, the size and the like of the substrate, but it may be suitably selected according to the application, the purposes and the like of the luminescent device. In general, a plate-like substrate is preferred as the shape of the substrate. The structure of the substrate may be a monolayer structure or a laminated structure. Furthermore, the substrate may be formed from a single member or from two or more members.

Although the substrate may be in a transparent and colorless, or a transparent and colored condition, it is preferred that the substrate is transparent and colorless from the viewpoint that the substrate does not scatter or attenuate light emitted from the organic emissive layer.

A moisture permeation preventive layer (gas barrier layer) may be provided on the front surface or the back surface of the substrate.

For a material of the moisture permeation preventive layer (gas barrier layer), inorganic substances such as silicon nitride and silicon oxide may be preferably applied. The moisture permeation preventive layer (gas barrier layer) may be formed in accordance with, for example, a high-frequency sputtering method or the like.

In case of applying a thermoplastic substrate, a hard-coat layer or an under-coat layer may be further provided as necessary.

10) Anode

An anode in the present invention may generally have a function as an electrode for supplying positive holes to the organic compound layer, and while there is no particular limitation as to the shape, the structure, the size and the like, it may be suitably selected from among well-known electrode materials according to the application and the purpose thereof.

As materials for the anode, for example, metals, alloys, metal oxides, electric conductive compounds, and mixtures thereof are preferably used, wherein those having a work function of 4.0 eV or more are preferred. Specific examples of the anode materials include electric conductive metal oxides such as tin oxides doped with antimony, fluorine or the like (ATO, and FTO), tin oxide, zinc oxide, indium oxide, indium tin oxide (ITO), and indium zinc oxide (IZO); metals such as gold, silver, chromium, and nickel; mixtures or laminates of these metals and the electric conductive metal oxides; inorganic electric conductive materials such as copper iodide, and copper sulfide; organic electric conductive materials such as polyaniline, polythiophene, and polypyrrole; and laminates of these inorganic or organic electron-conductive materials with ITO.

The anode may be formed on the substrate, for example, in accordance with a method which is appropriately selected from among wet methods such as a printing method, and a coating method and the like; physical methods such as a vacuum deposition method, a sputtering method, and an ion plating method and the like; and chemical methods such as CVD and plasma CVD methods and the like with consideration of the suitability with a material constituting the anode. For instance, when ITO is selected as a material for the anode, the anode may be formed in accordance with a DC or high-frequency sputtering method, a vacuum deposition method, an ion plating method or the like.

In the organic electroluminescence device of the present invention, a position at which the anode is to be formed is not particularly restricted, but it may be suitably selected according to the application and the purpose of the luminescent device. The anode may be formed on either the whole surface or a part of the surface on either side of the substrate.

For patterning to form the anode, a chemical etching method such as photolithography, a physical etching method such as etching by laser, a method of vacuum deposition or sputtering through superposing masks, and a lift-off method or a printing method may be applied.

A thickness of the anode may be suitably selected dependent on the material constituting the anode, and is not definitely decided, but it is usually in the range of around 10 nm to 50 μm, and 50 nm to 20 μm is preferred.

A value of electric resistance of the anode is preferably 10³ Ω/□ or less, and 10² Ω/□ or less is more preferable.

The anode in the present invention can be colorless and transparent or colored and transparent. For extracting luminescence from the transparent anode side, it is preferred that a light transmittance of the anode is 60% or higher, and more preferably 70% or higher. The light transmittance in the present invention can be measured by means well known in the art using a spectrophotometer.

Concerning the transparent anode, there is a detailed description in “TOUMEI DENNKYOKU-MAKU NO SHINTENKAI (Novel Developments in Transparent Electrode Films)” edited by Yutaka Sawada and published by C.M.C. in 1999, the contents of which are incorporated by reference herein. In the case where a plastic substrate of a low heat resistance is applied, it is preferred that ITO or IZO is used to obtain a transparent anode prepared by forming the film at a low temperature of 150° C. or lower.

11) Cathode

The cathode in the present invention may generally have a function as an electrode for injecting electrons to the organic compound layer, and there is no particular restriction as to the shape, the structure, the size and the like. Accordingly, the cathode may be suitably selected from among well-known electrode materials.

As the materials constituting the cathode, for example, metals, alloys, metal oxides, electric conductive compounds, and mixtures thereof may be used, wherein materials having a work function of 4.5 eV or less are preferred. Specific examples thoseof include alkali metals (e.g., Li, Na, K, Cs or the like); alkaline earth metals (e.g., Mg, Ca or the like); gold; silver; lead; aluminum; sodium-potassium alloys; lithium-aluminum alloys; magnesium-silver alloys; rare earth metals such as indium and ytterbium; and the like. They may be used alone, but it is preferred that two or more of them are used in combination from the viewpoint of satisfying both of stability and electron injectability.

Among these, as the materials for constituting the cathode, alkaline metals or alkaline earth metals are preferred in view of electron injectability, and materials containing aluminum as the major component are preferred in view of excellent preservation stability.

The term “material containing aluminum as the major component” refers to a material that material exists in the form of aluminum alone; alloys comprising aluminum and 0.01% by mass to 10% by mass of an alkaline metal or an alkaline earth metal; or mixtures thereof (e.g., lithium-aluminum alloys, magnesium-aluminum alloys and the like).

As for materials for the cathode, they are described in detail in JP-A Nos. 2-15595 and 5-121172, the contents of which are incorporated by reference herein.

A method for forming the cathode is not particularly limited, but it may be formed in accordance with a well-known method. For instance, the cathode may be formed in accordance with a method which is appropriately selected from among wet methods such as a printing method, and a coating method and the like; physical methods such as a vacuum deposition method, a sputtering method, and an ion plating method and the like; and chemical methods such as CVD and plasma CVD methods and the like, while taking the suitability to a material constituting the cathode into consideration. For example, when a metal (or metals) is (are) selected as a material (or materials) for the cathode, one or two or more of them may be applied at the same time or sequentially in accordance with a sputtering method or the like.

For patterning to form the cathode, a chemical etching method such as photolithography, a physical etching method such as etching by laser, a method of vacuum deposition or sputtering through superposing masks, and a lift-off method or a printing method may be applied.

In the present invention, a position at which the cathode is to be formed is not particularly restricted, but it may be formed on either the whole or a part of the organic compound layer.

Furthermore, a dielectric material layer made of a fluoride, an oxide or the like of an alkaline metal or an alkaline earth metal may be inserted in between the cathode and the organic compound layer with a thickness of 0.1 nm to 5 nm, wherein the dielectric layer may serve as one kind of electron injection layer. The dielectric material layer may be formed in accordance with, for example, a vacuum deposition method, a sputtering method, an on-plating method or the like.

A thickness of the cathode may be suitably selected dependent on materials for constituting the cathode and is not definitely decided, but it is usually in the range of around 10 nm to 5 μm, and 50 nm to 1 μm is preferred.

Moreover, the cathode may be transparent or opaque. The transparent cathode may be formed by preparing a material for the cathode with a small thickness of 1 nm to 10 nm, and further laminating a transparent electric conductive material such as ITO or IZO thereon.

### 2. Inorganic Electroluminescence Device

An inorganic electroluminescence device includes first and second insulative films disposed between electrodes and comprising an oxide having a high dielectric constant, and a functional layer such as a light emitting layer comprising a sulfide interposed between the insulative films. As the insulative layer, materials such as tantalum pentoxide (Ta₂O₅), titanium oxide (TiO₂), yttrium oxide (Y₂O₃), barium titanate (BaTiO₃), and strontium titanate (SrTiO₃) can be used. As the light emitting layer, those using materials such as zinc sulfide (ZnS), calcium sulfide (CaS), strontium sulfide (SrS) or barium thioaluminate (BaAl₂S₄) as a host material of the light emitting layer and containing a micro-amount of transition metal elements such as manganese (Mn) and rare earth elements such as europium (Eu) cerium (Ce) or terbium (Tb), as a light emission center can be used.

### 3. Photoelectronic Conversion Device

the photoelectronic conversion device includes functional layers such as a semiconductor layer which is put to pn-junction or pin-junction between the electrodes, and X-ray photoconductor layer generating charges by X-ray irradiation, which can be utilized for photodetectors, solar cells, X-ray detectors, etc. While materials are selected properly depending on the respective application uses, amorphous silicon (a-Si), polycrystal silicon, amorphous selenium (a-Se), cadmium sulfide (CdS), cadmium telluride (CdTe), zinc oxide (ZnO), lead oxide (PbO), lead iodide (PbI₂), or Bi₁₂(Ge, Si)O₂₀ can be used. They are optionally doped with impurities to control the conduction type.

### 4. Piezoelectric Conversion Device

A piezoelectric conversion device includes functional layers such as layers generating strains by voltage between electrodes, and layers generating a voltage by pressure or strain and can be utilized for pressure sensors, acceleration sensors, supersonic oscillators, and actuators. As the material for the piezoelectric layer, lead zirconate titanate (PZT), lead titanate (PbTiO₃), lithium niobate (LiNbO₃), lithium tantalate (LiTaO₃), lithium teteraborate (Li₂B₄O₇), aluminum nitride (AlN), quartz (SiO₂), or polyfluoro vinylidene (PVDF), etc. can be used.

The gas detection layer includes an n-semiconductor layer, etc. whose resistance value changes in a gas between electrodes. As the material for the n-semiconductor layer, tin oxide (SnO₂), zinc oxide (ZnO), etc. can be used. A composite material formed by carrying metal nano-particles such as of Ag in the pores silicon oxide (SiO₂) can also be used.

### 5. Other Device Constituent Material

### (Resin Sealing Layer)

In the functional device of the invention it is preferred to suppress the degradation of the device performance caused by contact with atmospheric air or oxygen or water content by means of a resin seal layer.

### (Material)

The resin material for the resin seal layer is not particularly restricted and acrylic resin, epoxy resin, fluoro resin, silicone resin, rubber resin, or ester resins can be used. Among them, the epoxy resin is preferred with a view point of water content preventive function. In the epoxy resin, thermosetting epoxy resin, or photocurable epoxy resin is preferred.

### (Manufacturing Method)

The manufacturing method of the resin seal layer is not particularly restricted and includes, for example, a method of coating a resin solution, a method of press bonding or hot press bonding a resin sheet or a method of dry polymerization by vapor deposition or sputtering, etc.

### (Film Thickness)

The thickness of the resin seal layer is 1 μm or more and, preferably, 1 mm or less. It is more preferably 5 μm or more and 100 μm or less and, most preferably, 10 μm or more and 50 μm or less. In a case where the thickness is smaller, the inorganic film may possibly be damaged upon mounting of the second substrate. Further, in a case where the thickness is larger, the thickness of the electroluminescence device per se increases to damage the thin film property as a feature of the organic electroluminescence device.

### (Sealing Adhesive)

The sealing adhesive used in the invention has a function of preventing intrusion of water content or oxygen from the edge.

### (Material)

As the material for the sealing adhesive, those identical with the materials used in the resin sealing layer can be used. Among all, an epoxy type adhesive is preferred with a view point of preventing water content and, among all, a photocurable epoxy type adhesive is preferred.

Further, addition of a filler to the materials described above is also preferred. The filler added to the sealant is preferably inorganic materials such as SiO₂, SiO (silicon oxide), SiON (silicon oxynitride), or SiN (silicon nitride). The addition of the filler increases the viscosity of the sealant to improve the fabricability and improve the humidity resistance.

### (Drying Agent)

The sealing adhesive may also contain a drying agent, the drying agent is preferably barium oxide, calcium oxide, or strontium oxide.

The addition amount of the drying agent to the sealing adhesive is, preferably, 0.01 mass % or more and 20 mass % or less and, more preferably, 0.05 mass % or more and 15 mass % or less. The addition effect of the drying agent is reduced in a case where the amount is smaller. Further, it is difficult to uniformly disperse the drying agent in the sealing adhesive in a case where the amount is larger, which is not preferred.

### (Formulation of Sealing Adhesive)

### Polymer Composition, Concentration

The sealing adhesive is not particularly restricted and those described above can be used. For example, the photo-curable epoxy adhesive includes XNR5516 manufactured by Nagase Chemtech Co. and the drying agent may be added to and dispersed therein.

### Thickness

The coating thickness of the sealing adhesive is preferably 1 μm or more and 1 mm or less. In a case where the thickness is smaller, the sealing adhesive can not be coated uniformly, which is not preferred. Further, in a case where the thickness is larger, water content intrusion paths are increased, which is not preferred.

### (Sealing Method)

In the invention, the sealing adhesive incorporated with the drying agent is coated in an optional amount by a dispenser or the like, a second substrate is stacked after coating, and they can be cured to obtain a functional device.

### 6. Edge Structure

### 1) Shape of the Edge other than the Edge for Taking Out Light Emission

At least one non-light emitting edge other than the light emitting edge for taking out light emission, an angle formed by the non-light emitting edge relative to the surface of the substrate supporting the stacked structure or the surface opposed to the surface of the substrate supporting the stacked structure is an acute angle (sometimes referred to as a tapered shape), and a light reflection layer is present at the non-light emitting edge. It is preferable that, at three non-light emitting edges other than the light emitting edge for taking out the light emission, the angle formed by the non-light emitting edge relative to the substrate surface is an acute angle, and that a light reflection layer is present at each of the three non-light emitting edges.

The angle formed by the non-light emitting edge is preferably 300 or more and 60° or less, and more preferably 40° or more and 50° or less.

Preferably, the area of the non-light emitting edge is 15% or more, and more preferably 30% or more, than the cross sectional area of the non-light emitting edge.

In a case where the angle formed by the edge exceeds 60°, since the non-light emitting edge area decreases, it is difficult to provide the light reflection layer, which is not preferred. On the other hand, in a case where it is less than 30°, the strength at the non-light emitting edge of the substrate is lowered to result in chipping or cracking which is not preferred.

The angle of the non-light emitting edge described above is an average angle. The shape of the inclined surface at the non-light emitting edge is not necessarily planar. It may be a stripe shape, stepwise shape, or a curved shape such as corrugating or ripple shape. Since the light reflection layer may be disposed more easily the larger the area of the inclined surface is and the smaller a portion hidden from a vapor deposition source is during vapor deposition, the angle of inclination and the edge shape are preferably selected such that the edge faces the vapor deposition source at an area wider than the cross sectional area.

The tapered shape is to be described more specifically with reference to the drawings. The illustrated drawings are for description with reference to several embodiments for understanding the present invention, and the invention is in no way restricted to them.

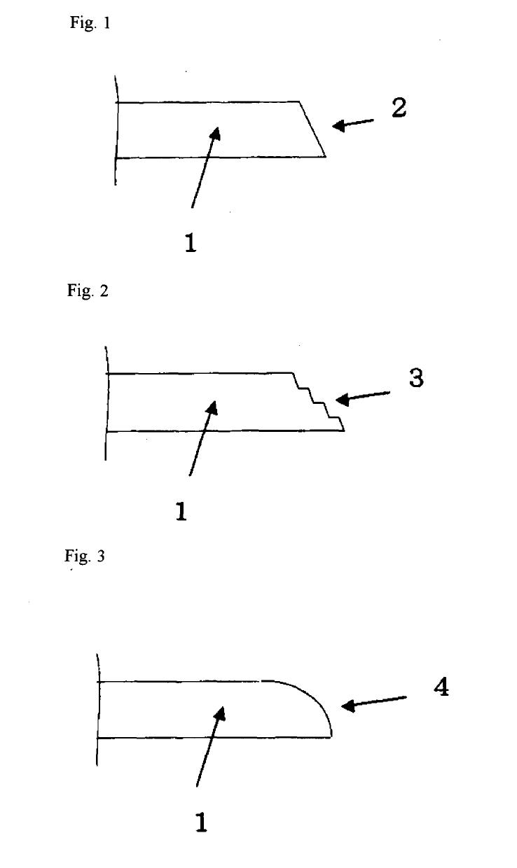

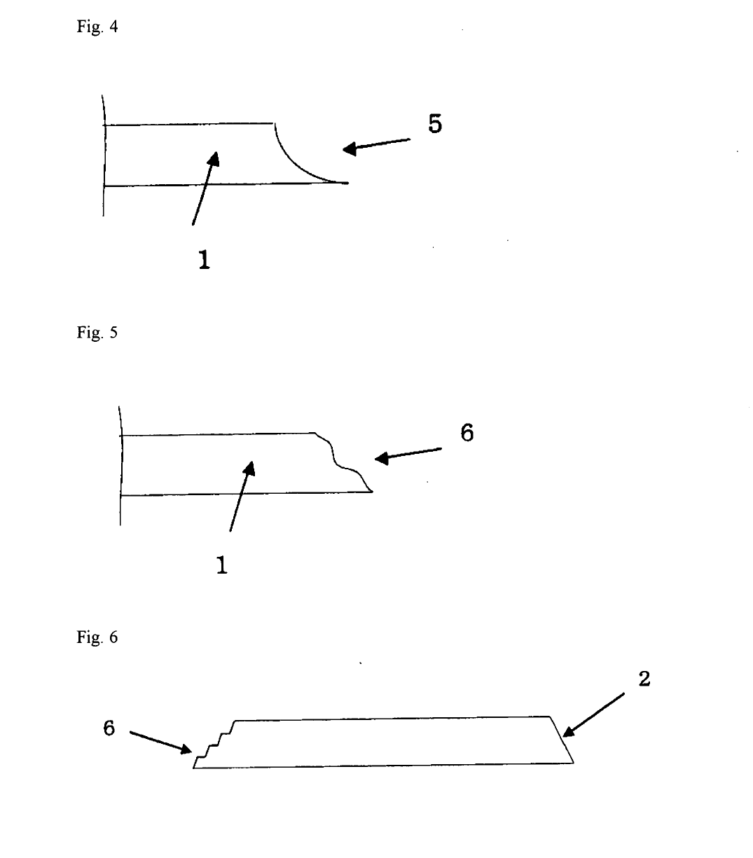

FIG. 1 shows an example of an edge shape formed by tapering at an acute angle such that an edge 2 of a substrate 1 is in a planar shape. FIG. 2 shows an example of an edge shape formed by tapering at an acute angle such that an edge 3 of the substrate 1 is in a stepwise shape. FIG. 3 shows an example of an edge shape formed by tapering at an acute angle such that an edge 4 of the substrate 1 is in a convex shape. FIG. 4 shows an example of an edge shape formed by tapering at an acute angle such that an edge 5 of the substrate 1 is in a concave shape. FIG. 5 shows an example of an edge shape formed by tapering at an acute angle such that an edge 6 of the substrate 1 is in a corrugated shape.

All of the non-light emitting edges have an in identical or different tapered shape. For example, FIG. 6 shows an example in which one edge 6 is made in a planar shape and the other edge 2 is fabricated into a stepwise shape.

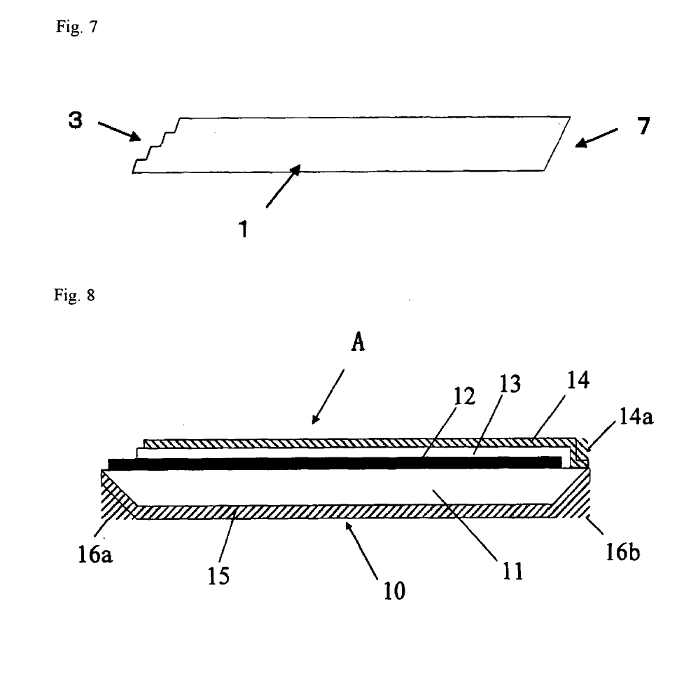

Alternatively, one non-light emitting edge may be tapered at an acute angle relative to the substrate surface having a light emitting layer and the other non-light emitting edge may be tapered at an acute angle relative to the substrate surface opposite to the surface having the light emitting layer (reverse tapering), and further, their shapes may be different. FIG. 7 shows an example in which the former edge 3 is formed stepwise and the latter edge 7 is tapered reversely in a planar shape.

FIG. 8 shows an example of a light emitting device of the invention which is a conceptual view of a cross sectional shape of a light take-out edge.

For easy understanding of the cross sectional shape of the invention, a sealing structure and other constituent elements not necessary for describing the constitution of the invention are omitted. The light emitting device A has four edges, in which one end face is used as a light take-out (light emitting) edge 10 and the remaining three edges are tapered and subjected to aluminum vapor deposition to constitute a light reflection surface. Accordingly, light generated in the light emitting layer is efficiently taken out from the light take-out edge. A surface opposite to the surface of a transparent substrate 11 for supporting a light emitting stack 13 is applied with tapering 16a, 16b in a planar shape at an acute angle. An ITO electrode 12 as an anode, a light emitting stack 13, and a cathode 14 are disposed and present on the other surface of the transparent substrate 11. The cathode 14 is formed of a light reflection agent such as aluminum and also functions as a light reflection layer.

Accordingly, since three non-light emitting edges other than the light take-out edge 10 are each covered with the aluminum reflection layer and the surface opposite to the surface disposed with the light emitting device is covered with an aluminum reflection layer 15, the light generated in the light emitting layer can be efficiently taken-out from the light take-out edge 10.

### 2) Light Reflection Layer

The light reflection layer disposed at the non-light emitting edge reflects the generated light and makes it possible to take-out the light efficiently from the light take-out edge. The light reflectance of the light reflection layer is preferably 50% or more, and more preferably 70% or more.

The light reflection layer is preferably formed by vapor deposition. This is preferably a metal or a metal oxide, and more preferably a metal such as aluminum, silver, gold, or chromium.

The layer is vapor deposited to a thickness preferably from 0.01 μm to 1 μm, and more preferably from 0.05 μm to 0.2 μm.

### 3) Manufacturing Method

One e method for manufacturing the edge light-emitting device according to the invention is a manufacturing method including disposing a stacked structure comprising a pair of electrodes and at least one light emitting layer interposed between the electrodes above a light permeable substrate, subsequently tapering an edge not taking-out light emission, and disposing a light reflection layer at the tapered edge.

Another manufacturing method includes tapering an edge, of a light permeable substrate, that does not constitute a light emission taking-out edge, subsequently disposing a stacked structure comprising a pair of electrodes and at least one light emitting layer interposed between the electrodes, on the substrate, and disposing a light reflection layer at the tapered edge.

The tapering referred to herein means processing for grinding a cross section of an edge so that the edge forms an acute angular shape with respect to the surface of the substrate having a device stacked structure or the surface opposite to the surface of the substrate supporting the stacked structure.

In the two manufacturing methods described above, steps other than the tapering are generally well known manufacturing for light emitting devices.

Accordingly, only the tapering method is to be described below.

The tapering can be conducted either after or before preparing the light emitting device. Any tapering method may be used for the edge so long as a desired edge shape can be attained. For example, a method of grinding by using an abrasive stone is preferably applicable to the invention. In this method, a substrate edge is brought into contact with a rotating abrasive stone in a state inclined at a desired angle thereto. The edge is ground by the abrasive stone to attain a substrate edge formed in a tapered shape relative to the substrate plane. In this case, since the edge is usually formed into a ground glass state, it may be optionally ground further to form a smooth plane. Other tapering methods include a sand blasting method or a pressing method. In the sand blasting method, fine particles of the abrasive stone are blown to the substrate edge, thereby applying tapering. In the pressing, the edge is fabricated into a tapered shape by using a die in the process of manufacturing a glass substrate, and then an organic EL device and reflection layer are prepared.

### EXAMPLES

The present invention is to be described more specifically by way of examples, but the invention is not restricted to the examples described below.

### Example 1

### 1. Manufacture of Device

### (Formation of Stripe Electrode)

An anode electrode comprising ITO was formed as a film by a sputtering method to a film thickness of 200 nm on a non-alkali glass substrate having a size of 25 mm (length)×25 mm (width)×1 mm (thickness) and re-shaped by wet etching.

### (Formation of Organic EL Layer)

Then, organic layers were deposited by using a vapor deposition mask having an opening at a predetermined position.

In this case, the organic EL layers were formed, with the following constitutions and layer thicknesses, by successively vacuum vapor depositing, for example, a hole injection layer comprising 30 nm of MTDATA (4,4′,4″-tris-(3-methylphenylphenylamino)-triphenylamine), a hole transport layer comprising 20 nm of α-NPD (N,N′-dinaphthyl-N,N′-diphenyl-(1,1′-biphenyl)-4,4′-diamine), 30 nm of a light emitting layer formed by doping a light emitting material, t(npa)py (1,3,6,8-tetra-(N-naphtnyl)-N-phenylamino-pyrene) to host Alq3 (tris-(8-hydroxynonynate)-aluminum), and 20 nm of an electron transport layer comprising Alq3.

Then, an upper electrode comprising (Al) was formed so as to cover the organic EL layers by using a vapor deposition mask for an upper electrode having an opening at a predetermined position to prepare an organic EL device.

A glass cap was adhered with an UV-curable adhesive so as to cover the organic EL device portion to form a seal.

### 2. Tapering

The following tapering was conducted to three sides not taking out an emission light of the obtained organic EL device.

Device 1A: Acute angle at an angle of 45°

Device 1B (Comparative Example): Not applied with tapering.

### (Description of Tapering Method)

The edge of the device 1A is in contact in a state of tilting a substrate surface at 45° to an abrasive stone of a glass grinding apparatus under rotation, and formed such that the edge has an angle of 45° relative to the substrate plane. Since an abrasive stone portion in a planar shape was used for the grinding apparatus, the edge of the glass substrate was in a planar shape. Among the substrate edges at four portions, identical fabrication was fabricated to all the portions in the same manner except for one portion. Only the substrate edge was cleaned with IPA such that the glass powder was not left near the substrate edge. The edge shape of the obtained device 1A was in the shape as shown in FIG. 1.

### 3. Vapor Deposition of Light Reflection Layer

The following light reflection layer was deposited under the same conditions to each of the samples. Upon vapor deposition, the device was adhered using a double faced tape to a substrate holder and the substrate and the vapor deposition source were arranged such that the Al vapor deposition source situated just below the substrate. In this case, the substrate was placed such that vapor deposition could be applied to the surface opposite to the formed with the light emitting device both for the device 1A and the device 1B. During Al vapor deposition, the substrate holder was rotated, so that Al was vapor deposited uniformly.

Aluminum vapor deposition condition: 10 Å/s (vapor deposition speed), 100 nm (thickness)

Thus, an organic EL device in which the bottom surface and the tapered three edges of the substrate 11 were film deposited over the entire surface with the Al light reflection layer. In the organic EL device, Al was slightly vapor deposited also to the not tapered edge at one portion as the light take-out edge to form a light reflection layer with unevenness.

Then, Al vapor deposited slightly to the not tapered edge as the light take-out edge was removed by grinding with the abrasive stone into a smooth edge of high light transmittance to form a light take-out end face.

With the operations described above, an edge light emitting organic EL device as shown in FIG. 8 was manufactured. The edge light emitting organic EL device was tapered at the edges for the three portions other than the light tape-out edge and the bottom and the tapered edges at the three portion of the substrate 11 were covered with the Al reflection layer.

### 4. Evaluation for Performance

### (Measurement for the Vapor Deposition State of Aluminum of Light Reflection Layer)

### (Measuring Method)

A voltage was applied to the completed light emitting device and absence or presence of leakage for light emission from the portion other than the light take-out portion was confirmed with naked eyes.

### (Result)

A voltage at 7 V was applied to the electrode of the device 1A and the device 1B to confirm the state of light emission. The device 1A was covered entirely with the reflection layer for the not light take-out edge and light emission could be confirmed only for the light take-out edge. On the contrary, in the device 1B, while the substrate planar portion was covered with Al and the light leakage was not observed, the Al vapor deposition film at the edge other than the light take-out edge was extremely thin and light emission was observed also from the edges other than the light take-out edge.

### (Measurement for the Edge Light Emitting Intensity)

### (Measuring Method)

A voltage at 7 V was applied to the device 1A and the device 1B and the light emission from the edges were measured by a brightness meter respectively.

### (Result).

The light emitting intensity from the light take-out edge was 2200 cd/m² for the device 1A and 1050 cd/m² for the device 1B in which about twice or more increase was observed for the light emitting intensity. While light emission from the edges other than the light take-out edge was 0 in the device 1A, light emission at 600 cd/m² was observed in the device 1B and light was emitted also from the not intended edges. It can be seen that the reflection layer at the edge of the device 1A was formed effectively by the method of the invention and the light emission from the desired edge was increased.

### Example 2

### 1. Manufacture of Light Emitting Device

An edge light-emitting device was prepared in the same manner as in Example 1 except for using the following inorganic EL device instead of the organic EL device in Example 1.

### (Formation of Inorganic EL Layer)

A first insulative film comprising tantalum pentoxide (Ta₂O₅) was formed as a film to 200 nm thickness so as to cover a portion of a substrate, a stripe electrode and a smoothed insulative layer by sputtering at 0.2 nm/sec sputter rate, with a radio frequency power at 1 kW, at a substrate temperature of 200° C., while maintaining the pressure in the apparatus at 1 Pa in a mixed gas atmosphere of argon containing oxygen. Then, a light emitting layer comprising zinc sulfide (ZnS) with addition of 3 mol % manganese (Mn) was formed as a film to a thickness of 400 nm in a mixed gas atmosphere of argon containing hydrogen sulfide (H₂S) also by radio frequency sputtering at a substrate temperature of 350° C. Then, a second insulative film comprising tantalum pentoxide (Ta₂O₅) was formed as a film to a thickness of 200 nm in the same manner as for the first insulative layer.

After depositing each of the layers described above the substrate, a heat treatment was applied in vacuum at 10⁻⁴ Pa at 400° C. for one hour.

Then, an upper electrode comprising Al was formed so as to cover the inorganic EL layer by using a vapor deposition mask for upper electrode having an opening at a predetermined position, to manufacture an inorganic EL device.

Then, after sealing in the same manner as in Example 1, tapering was applied and a reflection layer was vapor deposited to manufacture a device 2A. A device formed with a reflection layer without applying tapering was formed as a device 2B.

### 2. Evaluation for Performance

Evaluation was conducted in the same manner as in Example 1.

### (Result)

An AC voltage at 150 V was applied to the electrodes of the device 2A and the device 2B, to confirm the state of light emission. In the device 2A, not light take-out edges were entirely covered with the reflection layer and light emission could be confirmed only for the light take-out edge. On the contrary, in the device 2B, while the substrate planar portion was covered with Al and the light leakage was not observed, the Al vapor deposition film at the edges other than the light take-out edge was extremely reduced in the thickness and light emission was observed also from the edges other than the light take-out edge.

### Example 3

A device 3A was manufactured quite in the same manner except for changing the abrasive stone portion of the glass grinding apparatus used in Example 1 to a concave surface shape. The edge of the obtained organic EL device formed a smooth convex shape as shown in FIG. 3. The obtained device 3C was evaluated by the same evaluation method. The leakage of light was not observed at all from the edge formed with the reflection layer due to the Al reflection film formed effectively as a film. Further, a high edge light emitting brightness of 2230 cd/m² substantially equal with that of the device 1A was observed from a desired edge.

### Example 4

An edge light emitting organic EL device 4A was manufactured quite in the same manner as in the device 1A except for conducting the step of fabricating the edge of the glass substrate used for the device 1A before film deposition of the ITO electrode. The obtained device 4A was evaluated by the same method as that in Example 1A. The leakage of light was not observed at all from the edge formed with the reflection layer due to the Al reflection film deposited effectively as a film. Further, a high edge light emitting brightness of 2200 cd/m² substantially equal with that of the device 1A was observed from a desired edge.

What is claimed is:

1. An edge light-emitting device having, on a light permeable substrate, a stacked structure comprising a pair of electrodes and at least one light emitting layer interposed between the electrodes, in which light emission is taken-out from a light emitting edge of the stacked structure, wherein at least one non-light emitting edge other than the light emitting edge for taking out the light emission, an angle formed by the non-light emitting edge relative to a surface of the substrate supporting the stacked structure or a surface opposed to the surface of the substrate supporting the stacked structure is an acute angle, and the non-light emitting edge has a light reflection layer.

2. An edge light-emitting device according to claim 1, wherein at three non-light emitting edges other than the light emitting edge for taking out light emission, the angle formed by the non-light emitting edge is an acute angle and the non-light emitting edge has a light reflection layer.

3. An edge light-emitting device according to claim 1, wherein the light reflection layer is a layer formed by vapor deposition.

4. An edge light-emitting device according to claim 1, wherein the angle formed by the non-light emitting edge is 300 to 600.

5. An edge light-emitting device according to claim 1, wherein the area of the non-light emitting edge is wider by 15% or more than the cross sectional area of the non-light emitting edge.

6. An edge light-emitting device according to claim 3, wherein the vapor deposition layer is a layer formed by vapor depositing a metal or a metal oxide.

7. An edge light-emitting device according to claim 1, wherein the light emitting device is an organic electroluminescence device.

8. An edge light-emitting device according to claim 1, wherein the light emitting device is an inorganic electroluminescence device.

9. A method of manufacturing an edge light-emitting device, the method comprising:
(1) disposing a stacked structure comprising a pair of electrodes and at least one light emitting layer interposed between the electrodes, on a light permeable substrate;
(2) subsequently tapering an edge that does not take out light emission; and
(3) disposing a light reflection layer at the tapered edge.

10. A method of manufacturing an edge light-emitting device, the method comprising:
(1) tapering an edge, of a light permeable substrate, that does not constitute a light emission taking-out edge;
(2) subsequently disposing a stacked structure comprising a pair of electrodes and at least one light emitting layer interposed between the electrodes, on the substrate; and
(3) disposing a light reflection layer at the tapered edge.
